(19) United States
(12) Patent Application Publication
(10) Pub. No.: US 2026/0090038 A1
(43) Pub. Date: Mar. 26, 2026

(54) FORKSHEET TRANSISTOR MULTILAYER BOTTOM ISOLATION REGION

(71) Applicant: International Business Machines Corporation, Armonk, NY (US)

(72) Inventors: Fabio Carta, Pleasantville, NY (US); Ruilong Xie, Niskayuna, NY (US); Tao Li, Slingerlands, NY (US); Kisik Choi, Watervliet, NY (US); Mahender Kumar, Clifton Park, NY (US); Ravikumar Ramachandran, Pleasantville, NY (US)

(21) Appl. No.: 18/893,183

(22) Filed: Sep. 23, 2024

(51) Int. Cl. H01L 29/06; H01L 29/08; H01L 29/78

(52) U.S. Cl. CPC H10D 62/116; H10D 30/797; H10D 62/118; H10D 62/151

(57) ABSTRACT

A semiconductor IC device includes an isolation bar, nanolayer channels in direct contact with the isolation bar, and a multilayer bottom isolation region in direct contact with the isolation bar. The multilayer bottom isolation region may include a bottom dielectric layer, a middle dielectric layer, and a top dielectric layer. The bottom dielectric layer and the top dielectric layer may be composed of a same first dielectric material. The multilayer bottom isolation region may allow for the formation of a backside contact without an associated backside contact placeholder, which may reduce pitch between transistors and allow for continued semiconductor IC device scaling.

### BACKGROUND

Semiconductor integrated circuit (IC) devices are increasingly scaled smaller and smaller in size. One type of a transistor that may be utilized by such scaled semiconductor IC devices is a forksheet transistor. A forksheet transistor typically includes multiple channels connected to a source and drain regions. Multiple forksheet transistor are tightly packed together to achieve dense circuitry, but how to electrically isolate the device at a tight pitch is an issue. The isolation bar enables a relatively closer transistor pitch, which may shrink the size of the semiconductor IC device.

### SUMMARY

In an embodiment of the disclosure, a semiconductor IC device is presented. The semiconductor IC device includes an isolation bar and nanolayer channels in direct contact with the isolation bar. The semiconductor IC device further includes a source/drain region in direct contact with the isolation bar and in direct contact with the nanolayer channels. The semiconductor IC device further includes a multilayer bottom isolation region in direct contact with the isolation bar.

In an embodiment of the disclosure, a semiconductor IC device is presented. The semiconductor IC device includes an isolation bar and nanolayer channels in direct contact with the isolation bar. The semiconductor IC device further includes a multilayer bottom isolation region in direct contact with the isolation bar. The respective sidewalls of the nanolayer channels are substantially coplanar with a sidewall of the multilayer bottom isolation region.

In an embodiment of the disclosure, a semiconductor IC device is presented. The semiconductor IC device includes an isolation bar and nanolayer channels in direct contact with the isolation bar. The semiconductor IC device further includes a multilayer bottom isolation region in direct contact with the isolation bar. The nanolayer channels and the multilayer bottom isolation region share a same substantially vertical bisector.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1 depicts cross-section views of a semiconductor IC device that includes a multilayer bottom isolation region, according to one or more embodiments of the disclosure.

FIG. 2 depicts a partial structure top-down view of an illustrative semiconductor IC device, according to one or more embodiments of the disclosure.

FIG. 3 through FIG. 21 depict various fabrication structure cross-section views of an illustrative semiconductor IC device that includes a multilayer bottom isolation region, according to one or more embodiments of the disclosure.

FIG. 22 depicts a method of fabricating a semiconductor IC device that includes a multilayer bottom isolation region, according to one or more embodiments of the disclosure.

### DETAILED DESCRIPTION

A transistor is a type of microdevice that may be fabricated in semiconductor IC device front-end-of-line (FEOL) fabrication operations. Conventional transistors, or the like, incorporate planar field effect transistors (FETs) in which current flows through a semiconducting channel between a source and a drain, in response to a voltage applied to the gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

A forksheet FET typically includes multiple parallel channels connected to a shared source and drain regions The isolation bar enables a relatively closer transistor pitch, which shrinks the size of the semiconductor IC device.

The flowcharts and cross-sectional diagrams in the drawings illustrate a method of fabricating a semiconductor IC device, such as a processor, field programmable gate array (FPGA), memory module, or the like. In some alternative implementations, the fabrication steps may occur in a different order than that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces. Accordingly, two surfaces may be referred to as substantially coplanar despite deviations from coplanarity, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 10:1 or greater.

For the sake of brevity, conventional techniques related to semiconductor IC device fabrication may or may not be described in detail and/or depicted herein. Moreover, the various tasks and process steps described herein can be incorporated into a more comprehensive procedure or process having additional steps or functionality not described and/or not depicted in detail herein. Various steps in the manufacture of semiconductor devices are well known and so, in the interest of brevity, many conventional steps will only be mentioned briefly herein, will be omitted entirely without providing the well-known process details, and/or will not be depicted.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modem microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain regions and uses electrons as the charge carrier. The pFET includes p-doped source and drain regions and uses holes as the charge carrier. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of a FET is related to the electrical conductivity of the channel material. If the channel material has a relatively high conductivity, the FET can be made with a correspondingly smaller wafer footprint. A method of increasing channel conductivity and decreasing FET size is to form the channel as a nanostructure, such as a nano wire, nano ribbon, nanolayer, nanosheet, or the like, hereinafter referred to as a nanolayer. For example, the forksheet FET provides a relatively small FET footprint by forming the channel region as a series of vertically stacked nanolayers. In a forksheet configuration, one or more nanolayers extend from the isolation bar and serve as the channel. A gate surrounds the exposed surfaces of the stacked nanolayers and regulates electron flow through the nanolayers between the source and drain regions. Forksheet FETs may be fabricated by forming alternating layers of active nanolayers and sacrificial nanolayers. The sacrificial nanolayers are released from the active nanolayers before the FET device is finalized. For n-type FETs, the active nanolayers are typically silicon (Si) and the sacrificial nanolayers are typically silicon germanium (SiGe). For p-type FETs, the active nanolayers can be SiGe and the sacrificial nanolayers can be Si. In some implementations, the active nanolayers of a p-type FET can be SiGe or Si, and the sacrificial nanolayers can be Si or SiGe. Forming the nanolayers from alternating layers of active nanolayers formed from a first type of semiconductor material (e.g., Si for n-type FETs, and SiGe for p-type FETs) and sacrificial nanolayers formed from a second type of semiconductor material (e.g., SiGe for n-type FETs, and Si for p-type FETs) may provide for superior channel electrostatics control, which is necessary for continuously scaling gate lengths.

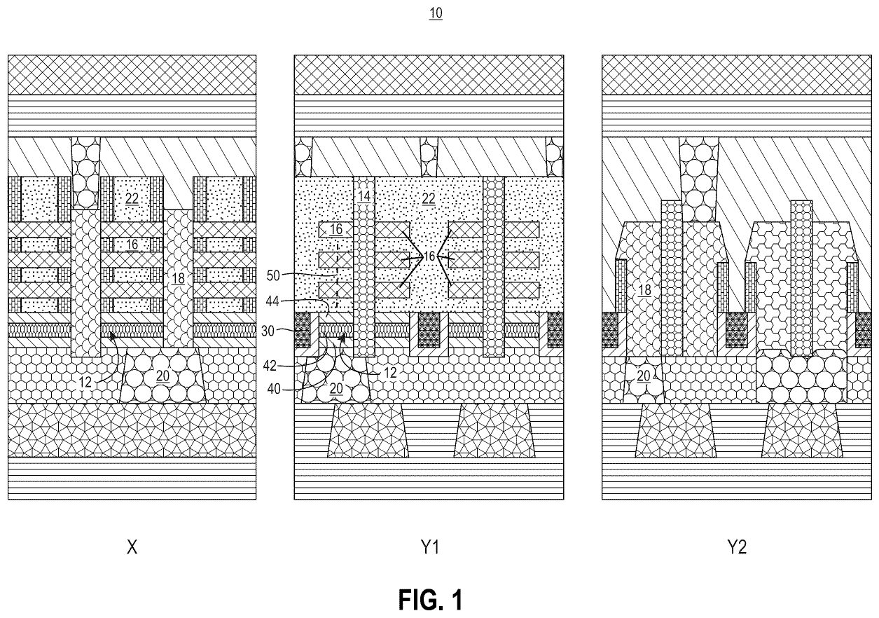

FIG. 1 depicts cross-section views of a semiconductor IC device 10. In an embodiment of the present disclosure, an instance of the semiconductor IC device 10 includes an isolation bar 14, nanolayer channels 16 in direct contact with the isolation bar 14, a source/drain region 18 in direct contact with the isolation bar 14 and in direct contact with the nanolayer channels 16, and a multilayer bottom isolation region 12 in direct contact with the isolation bar 14.

In an example, the source/drain region 18 is also in direct contact with the multilayer bottom isolation region 12. In an example, the semiconductor IC device 10 further includes a backside contact 20 in direct contact with a bottom surface of the source/drain region 18 and in direct contact with a bottom surface of the multilayer bottom isolation region 12. In an example, a bottom surface of the isolation bar 14 is below a bottom surface of the multilayer bottom isolation region 12.

In an example, the semiconductor IC device 10 further includes a gate structure 22 in direct contact with the nanolayer channels 16, in direct contact with the isolation bar 14, and in direct contact with a top surface of the multilayer bottom isolation region 12. In an example, a top surface of the multilayer bottom isolation region 12 is substantially coplanar with a bottom surface of the gate structure 22.

In an example, the semiconductor IC device 10 further includes a shallow trench isolation (STI) region 30 in direct contact with the multilayer bottom isolation region 12. In an example, the backside contact 20 is also in direct contact with the STI region 30 and wherein a top surface of the STI region 30 is substantially coplanar with the top surface of the multilayer bottom isolation region 12.

In an example, the multilayer bottom isolation region 12 includes a bottom dielectric layer 40 composed of a first dielectric material, a middle dielectric layer 42, and a top dielectric layer 44 composed of the first dielectric material. In an example, the middle dielectric layer 42 is composed of a second dielectric material different than the first dielectric material. In an example, respective sidewalls of the bottom dielectric layer 40, the middle dielectric layer 42, and the top dielectric layer 44 are in direct contact with the isolation bar 14.

In an embodiment of the present disclosure, another instance of the semiconductor IC device 10 includes the isolation bar 14, the nanolayer channels 16 in direct contact with the isolation bar 14, and the multilayer bottom isolation region 12 in direct contact with the isolation bar 14. In the present embodiment, respective sidewalls of the nanolayer channels 16 are substantially coplanar with a sidewall of the multilayer bottom isolation region 12.

In an example, this semiconductor IC device 10 further includes the source/drain region 18 in direct contact with the isolation bar 14 and in direct contact with the nanolayer channels 16. In an example, the source/drain region 18 is also in direct contact with the multilayer bottom isolation region 12. In an example, this semiconductor IC device 10 further includes the backside contact 20 in direct contact with the bottom surface of the source/drain region 18 and in direct contact with the bottom surface of the multilayer bottom isolation region 12.

In an example, the bottom surface of the isolation bar 14 is below a bottom surface of the multilayer bottom isolation region 12. In an example, this semiconductor IC device 10 further includes the gate structure 22 in direct contact with the nanolayer channels 16, in direct contact with the isolation bar 14, and in direct contact with a top surface of the multilayer bottom isolation region 12. In an example, the top surface of the multilayer bottom isolation region 12 is substantially coplanar with the bottom surface of the gate structure 22. In an example, this semiconductor IC device 10 further includes the STI region 30 in direct contact with the multilayer bottom isolation region 12.

In an embodiment of the present disclosure, another instance of the semiconductor IC device 10 includes the isolation bar 14, the nanolayer channels 16 in direct contact with the isolation bar 14, and the multilayer bottom isolation region 12 in direct contact with the isolation bar 14. In the present embodiment, the nanolayer channels 16 and the multilayer bottom isolation region 12 share a same substantially vertical bisector 50.

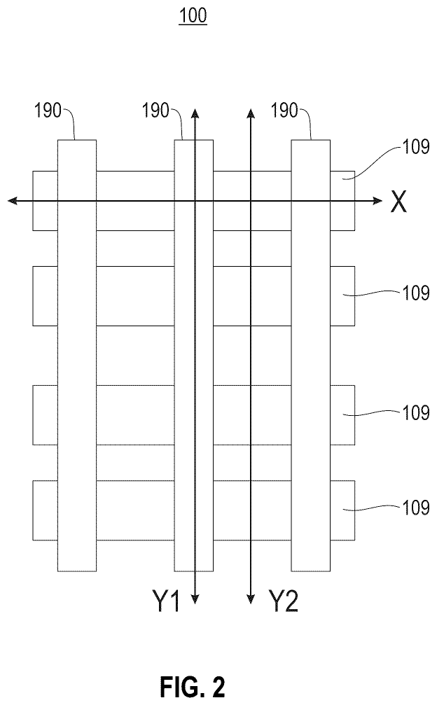

FIG. 2 depicts a partial structure top-down view of an illustrative semiconductor IC device 100, according to one or more embodiments of the disclosure. As currently depicted, semiconductor IC device 100 includes nanolayer rows 109 and replacement gate structures 190. FIG. 2 also depicts cross-sectional planes of the various cross-sectional views of at least some of the drawings. The X cross-sectional plane is through a nanolayer row 109 and across replacement gate structures 190. The Y1 cross-sectional plane is through a replacement gate structure 190 and across nanolayer rows 109. The Y2 cross-sectional plane between replacement gate structures 190 and across nanolayer rows 109. In some Figures, a Y cross-section is denoted which may be either the Y1 cross-section or the Y2 cross-section.

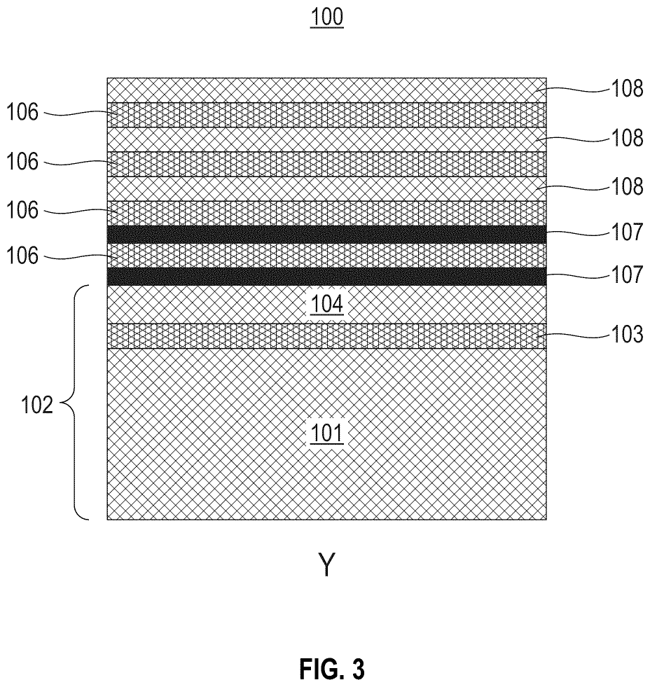

FIG. 3 depicts initial fabrication structure cross-section views of semiconductor IC device 100 that is to include a multilayer bottom isolation region. At the present fabrication stage, semiconductor IC device 100 may include a substrate structure 102, active nanolayers 108, sacrificial nanolayers 106, and sacrificial nanolayers 107.

The illustrative semiconductor IC device 100 may be formed by initially providing or forming the substrate structure 102. The substrate structure 102 may be a bulk-semiconductor substrate. In one example, the bulk-semiconductor substrate may be a silicon-containing material. In another example, the substrate structure may include an upper substrate 104, a lower substrate 101, and an etch stop layer 103 between the upper substrate 104 and the lower substrate 101. The upper substrate 104 and the lower substrate 101 may be comprised of any suitable material(s) including those listed above, and the etch stop layer 103 may be a dielectric material with etch selectivity to one or both the upper substrate 104 and/or the lower substrate 101. In one example, the etch stop layer 103 may be an oxide and the substrate structure 102 may be referred to as a buried oxide (BOX) substrate. In another example, the lower substrate 101 may be composed of Si. The etch stop layer 103 may be composed of Silicon Germanium (SiGe) and may be epitaxially grown from the top surface of lower substrate 101 and the upper substrate 104 may be composed of Si and may be epitaxially grown from the top surface of etch stop layer 103.

The illustrative semiconductor IC device 100 may be further fabricated by forming nanolayers over the substrate structure by forming a series or predetermined order of sacrificial nanolayers 106, sacrificial nanolayers 107, and active nanolayers 108, thereupon. In certain examples, a bottom most sacrificial nanolayer 107 is initially formed directly on an upper surface of the substrate structure 102. In other examples, certain layer(s) may be formed between the upper surface of the substrate structure 102 and the bottom most sacrificial nanolayer 107.

The sacrificial nanolayers 107 can have Ge percentages of 55% or greater. The sacrificial nanolayers 106 can have Ge percentages ranging from 20% to 45%. In an implementation, the sacrificial nanolayer 106, sacrificial nanolayer 107, and active nanolayer 108 pattern may be formed by epitaxially growing each layer until the desired number and desired thicknesses of the layers are achieved. Any number of nanolayers can be provided. Epitaxial materials can be grown from gaseous or liquid precursors. For example, epitaxial materials can be grown using vapor-phase epitaxy (VPE), molecular-beam epitaxy (MBE), liquid-phase epitaxy (LPE), or other suitable processes.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

Although it is specifically contemplated that the sacrificial nanolayers 106 and the sacrificial nanolayers 107 can be formed from SiGe and that the active nanolayers 108 can be formed from Si, it should be understood that any appropriate materials can be used instead, as long as the semiconductor materials have etch selectivity with respect to one or more of the others, as is consistent with the description of the fabrication stages herein.

Although it is specifically contemplated that the sacrificial nanolayers 106, the sacrificial nanolayers 107, and the active nanolayers 108 are formed by epitaxial growth, such nanolayers can be formed by any appropriate mechanism, such as chemical vapor deposition (CVD), physical vapor deposition (PVD), atomic layer deposition (ALD), or gas cluster ion beam (GCIB) deposition, or the like.

In certain embodiments, the nanolayers have a vertical thickness ranging, for example, from approximately 3 nm to approximately 20 nm. In certain embodiments, the nanolayers have a vertical thickness ranging, for example, from approximately 3 nm to approximately 10 nm. Although the range of 3-20 nm is cited as an example range of thickness of the nanolayers, other thickness of these nanolayers may be used. In certain examples, certain of the nanolayers may have different thicknesses relative to one another. For example, as depicted, the thickness of sacrificial nanolayers 107 may be smaller relative to either sacrificial nanolayers 106 or active nanolayers 108.

In certain examples, it may be desirable to have a small vertical spacing (VSP) between adjacent active nanolayers 108 to reduce the parasitic capacitance and to improve circuit speed. For example, the VSP (the distance between vertically adjacent active nanolayers 108) may range from 5 nm to 15 nm. However, the VSP must be of a sufficient value to accommodate the formation of a gate structure that is to be formed in the spaces created by later removal of respective portions of the sacrificial nanolayers 106. In a particular example, the thickness of sacrificial nanolayers 107 may be 4 to 8 nm, the thickness of sacrificial nanolayers 106 may greater than 8 nm to 20 nm, and the thickness of active nanolayers 108 may greater than 8 nm to 20 nm.

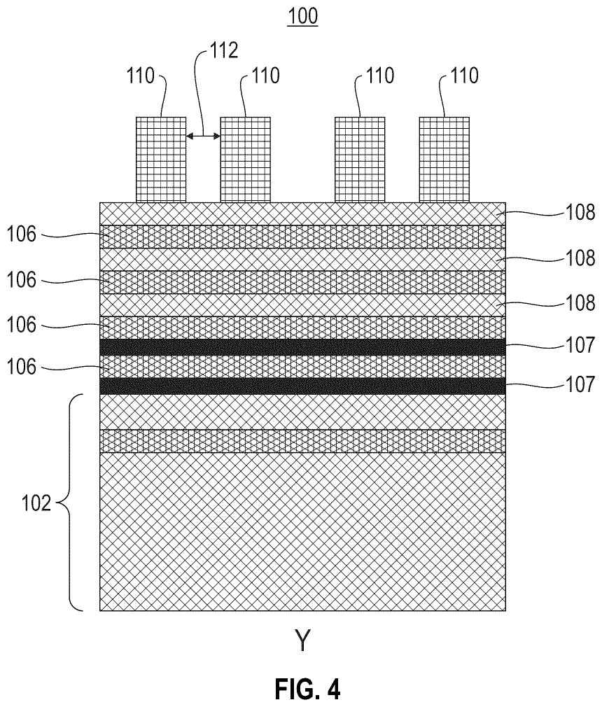

FIG. 4 depicts a fabrication structure cross-section view of the semiconductor IC device 100 that is to include a multilayer bottom isolation region, according to one or more embodiments of the disclosure. In the depicted fabrication stage, a mask 110 may be formed and patterned.

The mask 110 may be formed on the uppermost nanolayer. The mask 110 may be comprised of any suitable mask material(s). The mask 110 may be patterned and used to at least partially perform the nanolayer row 109 patterning process. The mask 110 may be patterned by lithography and etching processes. The patterned mask 110 may define a horizontal dimension 112 that may define a pitch between adjacent gate structures. Likewise, the patterned mask 110 may define a horizontal dimension that defines a gate length for subsequently formed gate structures.

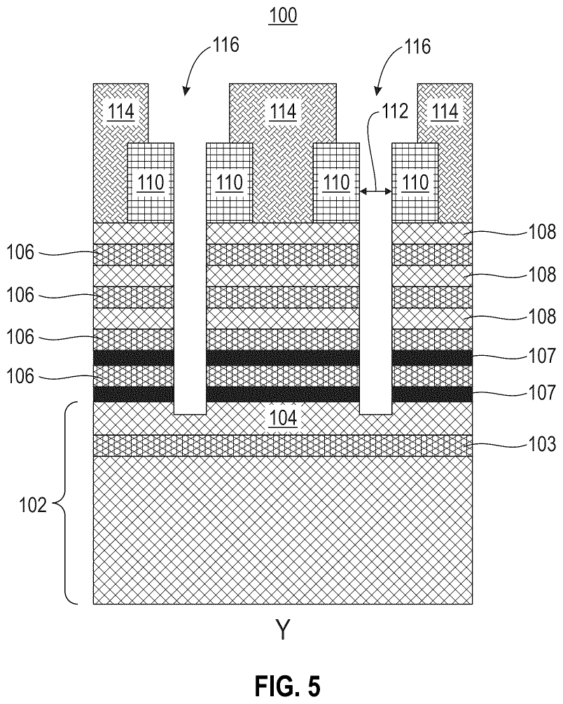

FIG. 5 depicts a fabrication structure cross-section view of the semiconductor IC device 100 that is to include a multilayer bottom isolation region, according to one or more embodiments of the disclosure. In the present fabrication stage, an isolation bar opening 116 within the nanolayers may be formed.

The isolation region opening 116 may be formed by forming a mask 114 upon the semiconductor IC device 100 and patterning the mask 114 to form the isolation bar opening(s) 116 by removing a portion of the mask 114 above the horizontal dimension 112. The mask 114 may generally protect the portions of the semiconductor IC device 100 that shall not be subjected to the etch process or processes that are utilized to form the isolation bar opening(s) 116. The mask 114 may consist of appropriate mask materials, such as those utilized for mask 110 or may further be an organic planarization layer (OPL).

The isolation bar opening 116 may further be formed by any suitable material removal process (e.g., reactive ion etching (RIE)) that removes portions of the nanolayers down to the level of or into the substrate structure 102. Following the isolation bar opening 116 formation, the one or more nanolayer rows may be partially formed. For example, the isolation bar openings 116 may form a boundary between forksheet transistor cells. In other words, the isolation bar openings 116 may form a boundary between like polarity forksheet transistors.

The isolation bar opening(s) 116 horizontal dimension 112 may be chosen so as to adequately electrically isolate the adjacent nanolayer rows when a predetermined dielectric or isolation material with a predetermined dielectric constant is deposited therein. The depth of the isolation bar opening(s) 116 may be controlled to be below the top surface of the substrate structure 102. For example, the depth or bottom of the one or more isolation bar opening(s) 116 lay within the upper substrate 104 and may be above the etch stop layer 103. Subsequently, the mask 114 may be removed by a etch, OPL ash, or the like.

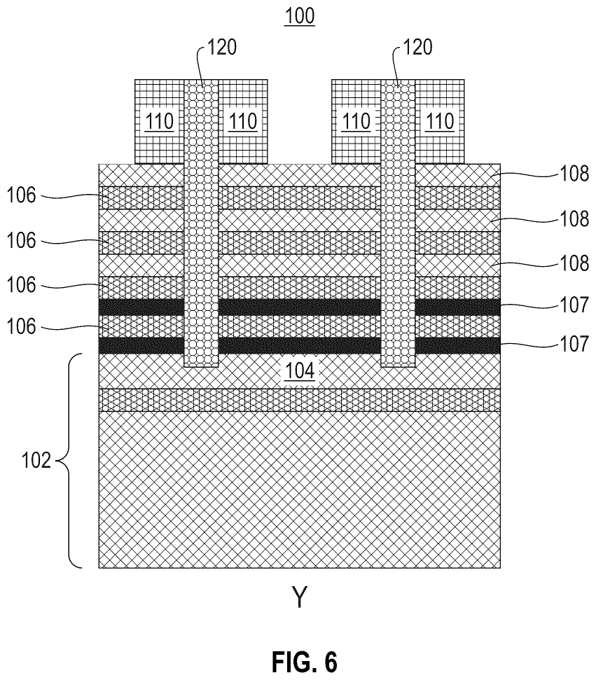

FIG. 6 depicts a fabrication structure cross-section view of the semiconductor IC device 100 that is to include a multilayer bottom isolation region, according to one or more embodiments of the disclosure. In the depicted fabrication stage, isolation bar 120 may be formed.

In an example, isolation bar 120 may be formed by forming an isolation bar layer to a thickness above the top surface of the mask 110 filling the isolation bar opening 116. For clarity, within the isolation bar opening 116, the isolation bar layer may be formed directly upon respective sidewalls of the sacrificial nanolayers 106, directly upon respective sidewalls of the sacrificial nanolayers 107, directly upon respective sidewalls of the active nanolayers 108, directly upon the mask 110, and directly upon the substrate structure 102.

Excess portion(s) of isolation bar layer may be removed by a substrative removal technique, such as an isotropic etch. The subtractive removal technique may generally remove the portion(s) of the isolation bar layer that are not pinched-off (i.e., located within respective isolation bar opening(s) 116). The isolation bar layer that remains within the isolation bar opening 116 may generally form the isolation bar 120. In examples, the isolation bar 120 may be composed of isolation material(s), such as a silicon oxide, silicon nitride, or the like.

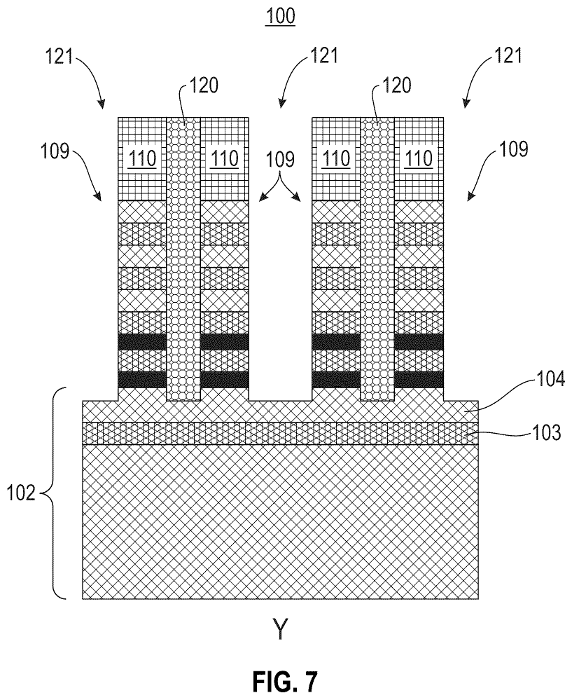

FIG. 7 depicts a fabrication structure cross-section view of the semiconductor IC device 100 that is to include a multilayer bottom isolation region, according to one or more embodiments of the disclosure. In the depicted fabrication stage, nanolayer rows 109 may be formed.

The nanolayer rows 109 may be formed by forming shallow trench isolation (STI) region opening(s) 121 using the patterned mask 110. The STI region opening(s) 121 may be formed by any suitable material removal process (e.g., reactive ion etching (RIE)) that removes portions of the nanolayers down to the level of or into the substrate structure 102. Following the STI region opening 121 formations, the one or more nanolayer rows 109 may be formed. For example, the STI region opening 121 may form a boundary between different polarity forksheet transistors.

The removal of undesired portion(s) of the nanolayers may further remove undesired portions of substrate structure 102 that are adjacent to respective footprints of nanolayer rows 109 to form the STI region openings 121 within at least the upper substrate 104. The etch may be timed or otherwise controlled to stop the removal of the substrate structure 102 such that the depth or bottom of the one or more STI region openings 121 has a predetermined or desired dimension. For example, the depth or bottom of the one or more STI region openings 121 may be above the etch stop layer 103.

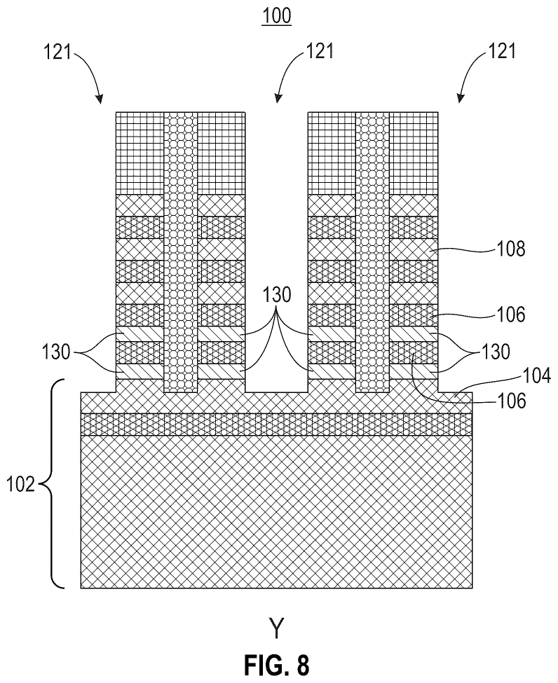

FIG. 8 depicts a fabrication structure cross-section view of the semiconductor IC device 100 that is to include a multilayer bottom isolation region, according to one or more embodiments of the disclosure. In the depicted fabrication stage, sacrificial nanolayers 107 may be removed, and are therefore not shown, and a respective isolation layer 130 may be formed in place thereof.

The sacrificial nanolayers 107 may be removed by a reactive ion etch (RIE) process, which can remove portions of the sacrificial nanolayers 107 selective to the sacrificial nanolayers 106, the active nanolayers 108, the upper substrate 104, the mask 110, and the isolation bar 120. When the sacrificial nanolayers 107 are composed of SiGe and when active nanolayers 108 are Si, the directional RIE can use a boron-based chemistry or a chlorine-based chemistry, for example, which recesses or removes the exposed end portions of sacrificial nanolayers 107 selective thereto.

The illustrated semiconductor IC device 100 may be further fabricated by next forming a respective isolation layer 130 within each indent. The one or more isolation layers 130 can be formed by ALD or CVD or any other suitable deposition technique that deposits a dielectric material within the indent(s), thereby forming the isolation layers 130. In some examples, the isolation layer 130 are composed of a low-x dielectric material (a material with a lower dielectric constant relative to SiO₂), SiN, SiO, SiBCN, SiOCN, SiCO, etc. or any other suitable dielectric material. In certain implementations, after the formation of the isolation layer 130, a directional etch process is performed to create substantially vertical sidewalls of the isolation layer 130 that are coplanar with the substantially vertical sidewalls of the active nanolayers 108 associated with the STI region openings 121.

In the depicted example, a bottom isolation layer 130 is between the upper substrate 104 and the bottommost sacrificial nanolayer 106 and an upper isolation layer is between the bottommost sacrificial nanolayer 106 and a higher sacrificial nanolayer 106.

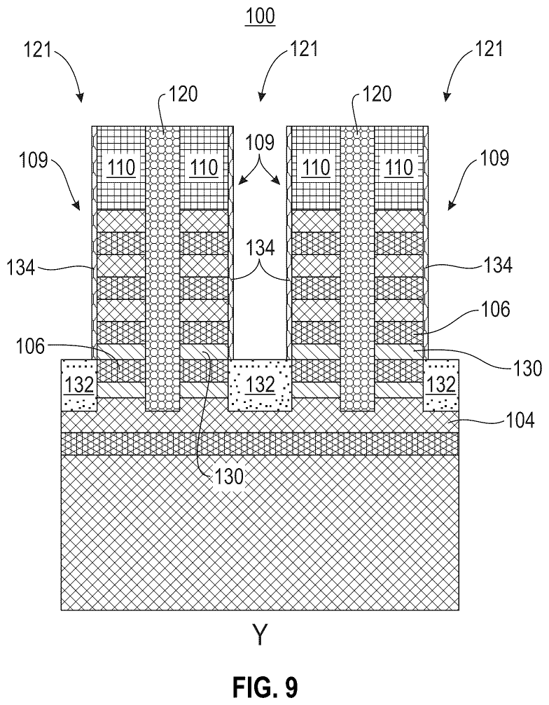

FIG. 9 depicts a fabrication structure cross-section view of the semiconductor IC device 100 that is to include a multilayer bottom isolation region, according to one or more embodiments of the disclosure. In the depicted fabrication stage, a sacrificial plug 132 and a protective spacer 134 may be formed within STI region openings 121.

A sacrificial plug 132 may be formed within each STI region opening 121 and may generally enclose or protect the bottommost sacrificial nanolayer 106 within each nanolayer stack so that the protective spacer 134 is not formed thereupon. Each sacrificial plug 132 may be composed of the same semiconductor material relative to the semiconductor material of the sacrificial nanolayer(s) 106. The sacrificial plug 132 may be formed by depositing the applicable semiconductor material within each STI region opening 121 between nanolayer rows 109 and performing an etch back to remove the semiconductor material generally above the bottom surface of the bottommost sacrificial nanolayer 106.

The protective spacers 134 may be formed by a conformal deposition of a dielectric material layer that has etch selectivity to the material of the sacrificial nanolayers 106. The dielectric material layer may be deposited upon the exposed sidewalls of the nanolayer rows 109, upon mask 110, upon the sacrificial plug 132, and upon the isolation bar 120. Subsequently, undesired generally horizontal portions of dielectric material layer may be removed while desired generally vertical portions the dielectric material layer may be retained and thereby form the protective spacers 134. The undesired portions of dielectric material may be removed by a directional ion etch, such as a reactive ion etch (RIE). The protective spacers 134 may generally be formed upon the exposed sidewalls of the sacrificial nanolayers 106 and the active nanolayers 108 within the nanolayer rows 109. As depicted, the protective spacers 134 may further be formed upon the exposed sidewalls of the pattern mask 110.

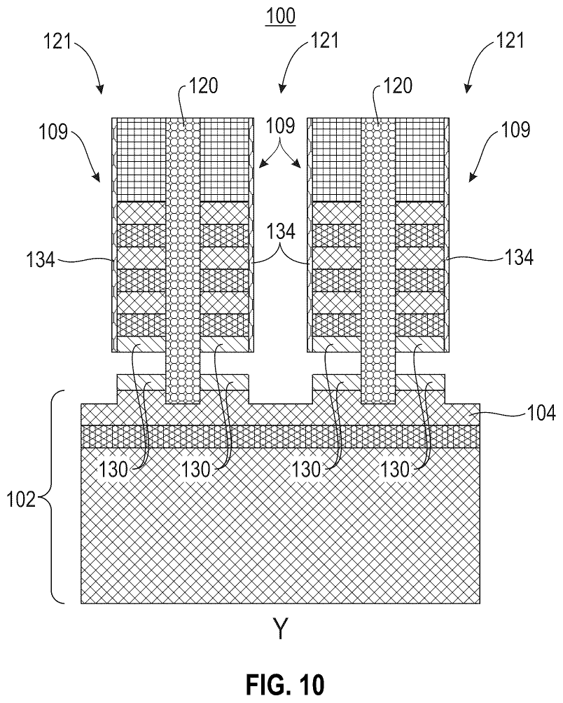

FIG. 10 depicts a fabrication structure cross-section view of the semiconductor IC device 100 that is to include a multilayer bottom isolation region, according to one or more embodiments of the disclosure. In the depicted fabrication stage, the sacrificial plug 132 and the bottommost sacrificial nanolayer 106 may be removed via the STI region opening 121.

The sacrificial plug 132 and the bottommost sacrificial nanolayer 106 may be removed by a reactive ion etch (RIE) process, which can remove the sacrificial plug 132 and the bottommost sacrificial nanolayer 106 selective to the isolation layer 130, the protective spacers 134, the upper substrate 104, the mask 110, and the isolation bar 120. When the sacrificial nanolayers 106 and the sacrificial plug 132 are composed of SiGe and when the upper substrate 104 is Si, the directional RIE can use a boron-based chemistry or a chlorine-based chemistry, for example, which recesses or removes the sacrificial plug 132 and the bottommost sacrificial nanolayer 106 selective to the above mentioned regions.

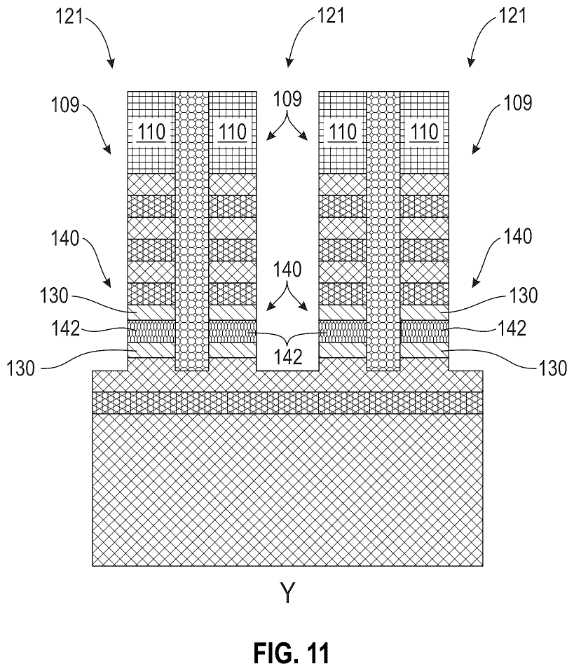

FIG. 11 depicts a fabrication structure cross-section view of the semiconductor IC device 100 that includes a multilayer bottom isolation region 140, according to one or more embodiments of the disclosure. In the depicted fabrication stage, the multilayer bottom isolation region 140 may be formed.

The multilayer bottom isolation region 140 may be formed by forming an isolation layer 142 in the indent or void formed by the removal of the bottommost sacrificial nanolayer 106 as depicted in FIG. 10. For example, the multilayer bottom isolation region 140 may be formed by forming an isolation layer 142 between the bottom isolation layer 130 and the top isolation layer 130.

The isolation layer 142 can be formed by ALD or CVD or any other suitable deposition technique that deposits a dielectric material within the indent or void formed by the removal of the bottommost sacrificial nanolayer 106 as depicted in FIG. 10, thereby forming the isolation layers 142. In some examples, the isolation layer 142 are composed of a low-x dielectric material (a material with a lower dielectric constant relative to SiO₂), SiN, SiO, SiBCN, SiOCN, SiCO, etc. or any other suitable dielectric material. For clarity, as the isolation layer(s) 130 and the isolation layer 142 may be formed in distinct fabrication stages, the dielectric material of the isolation layer(s) 130 and the isolation layer 142 may be different. Alternatively, the dielectric material of the isolation layer(s) 130 and the isolation layer 142 may be selected to be substantially the same.

In certain implementations, after the formation of the isolation layer 142, a directional etch process is performed to create substantially vertical sidewalls of the isolation layer 142 that are coplanar with the substantially vertical sidewalls of the active nanolayers 108 and sacrificial nanolayers 106 within the nanolayer rows 109 associated with the STI region openings 121. For example, a etch may remove excess isolation layer 142 removal and may further remove the protective spacers 134. The removal of the protective spacers 134 may expose the associated sidewalls of the active nanolayers 108, sacrificial nanolayers 106, and/or the mask 110 within the nanolayer rows 109, associated with the STI region openings 121.

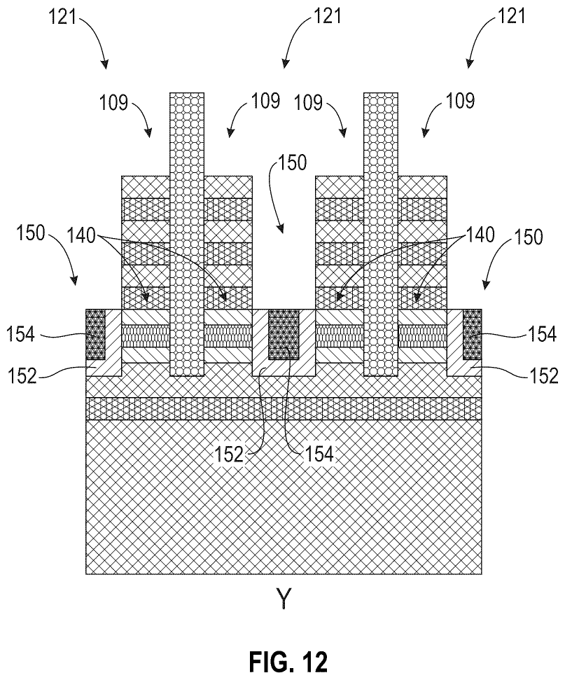

FIG. 12 depicts a fabrication structure cross-section view of the semiconductor IC device 100 that includes the multilayer bottom isolation region 140, according to one or more embodiments of the disclosure. In the depicted fabrication stage, STI regions 150 may be formed.

The STI regions 150 may be formed upon and/or within the substrate structure 102 within a respective STI region opening 121. The STI regions 150 may be formed by depositing electrical dielectric material(s) adjacent to the one or more nanolayer rows 109 within the STI region opening 121. A top surface of the one or more STI regions 150 may be above a top surface of the substrate structure 102, such as the top surface of the upper substrate 104.

The one or more STI regions 150 may have a volume and/or geometry that sufficiently electrically isolates components or features of neighboring transistors. For example, a particular STI region 150 may separate and/or electrically isolate a particular nanosheet row 109 from an adjacent nanosheet row 109, a particular STI region 150 may separate and/or electrically isolate a particular forksheet transistor from an adjacent forksheet transistor.

In an example, the STI region 150 may be formed by depositing a STI liner 152 within the STI region opening 121. Subsequently, the STI region 150 may be further formed by depositing STI dielectric material 154 upon the STI liner 152. A etch back, recess, or the like, may occur to remove undesired or over formed STI liner 152 and/or STI dielectric material 154, such that the nanolayer rows 109 are exposed and/or such that the top surface of the STI region 150 is substantially coplanar with or below a top surface of the multilayer bottom isolation region 140. The STI liner 152 may be composed of but not limited to a nitride, low-x nitride (i.e., a nitride material with a lower dielectric constant relative to SiO₂), or the like. The STI dielectric material 154 may be composed of but not limited to an oxide, low-x oxide (i.e., an oxide material with a lower dielectric constant relative to SiO₂), or the like.

Further, at the present fabrication stage, the mask 110 may be removed by a substrative removal technique, such as an etch.

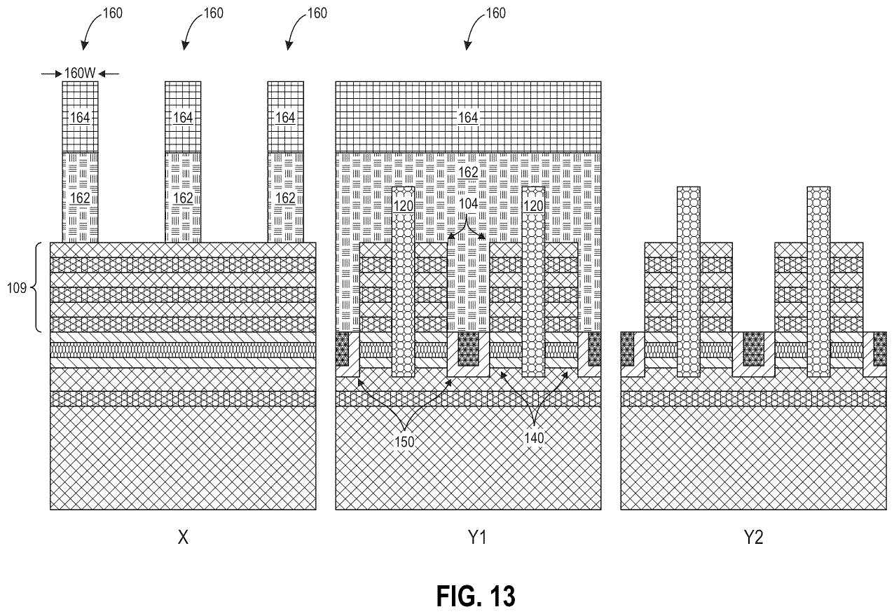

FIG. 13 depicts a fabrication structure cross-section view of the semiconductor IC device 100 that includes multilayer bottom isolation region 140, according to one or more embodiments of the disclosure. In the depicted fabrication stage, sacrificial gate structures 160 may be formed.

The sacrificial gate structures 160 may include a sacrificial gate liner (not shown), a sacrificial gate 162, and a sacrificial gate cap 164. The sacrificial gate structures 160 may be formed by initially depositing a sacrificial gate liner layer (e.g., a dielectric, oxide, or the like) upon the one or more nanolayer rows 109, upon and around the exposed portion of the isolation bar 120, and upon the exposed STI regions 150. The sacrificial gate structures 160 may further be formed by subsequently depositing a sacrificial gate layer (e.g., amorphous silicon, or the like) upon the sacrificial gate liner layer. The thickness of the sacrificial gate layer may be such that the top surface of the sacrificial gate layer is above the top surface of the isolation bar 120. The sacrificial gate structures 160 may further be formed by forming a gate cap layer upon the sacrificial gate layer. The gate cap layer may be formed by depositing a mask material, such as a hard mask material, such as silicon nitride, silicon oxide, combinations thereof, or the like, upon the sacrificial gate layer. The gate cap layer may be composed of one or more layers of masking materials to protect the sacrificial gate layer and/or other underlying materials during subsequent processing of semiconductor IC device 100.

The one or more sacrificial gate structures 160 may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner (not shown), the sacrificial gate 162, and the sacrificial gate cap 164, respectively, of each of the one or more sacrificial gate structures 160. The one or more sacrificial gate structures 160 can be formed on targeted regions or areas of semiconductor IC device 100 to define the gate length 160 W of one or more transistors and to provide sacrificial material for yielding targeted transistor structure(s).

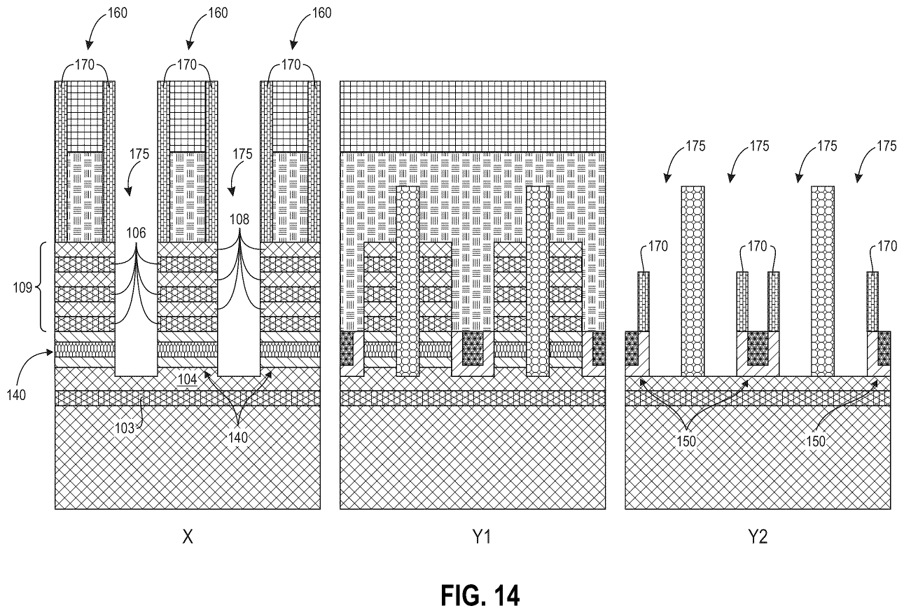

FIG. 14 depicts a fabrication structure cross-section view of the semiconductor IC device 100 that includes multilayer bottom isolation region 140, according to one or more embodiments of the disclosure. In the depicted fabrication stage, gate spacers 170 may be formed and S/D region canyons 175 may be formed.

The gate spacer(s) 170 may be formed by a conformal deposition of a dielectric material, such as silicon nitride, SiBCN, SiNC, SiN, SiCO, SiNOC, or a combination thereof, or the like, upon and around the nanolayer rows 109, upon and around the exposed portion of the isolation bar 120, upon the STI regions 150, and upon around the one or more sacrificial gate structures 160. Subsequently, undesired portions of dielectric material may be removed while desired portions the dielectric material may be retained and thereby form the gate spacers 170. The undesired portions of dielectric material may be removed by a directional ion etch, such as a reactive ion etch (RIE). The RIE may remove exposed or unprotected horizontal portions of the dielectric material while retaining protected vertical portions of the dielectric material to resultantly form the gate spacers 170.

The illustrated semiconductor IC device 100 may be further fabricated by forming S/D region canyons 175 within the one or more nanolayer rows 109 and multilayer bottom isolation region 140 between gate spacers 170 of neighboring sacrificial gate structures 160. In other words, a single nanolayer row 109 and multilayer bottom isolation region 140 may be separated, by one or more S/D region canyons 175, into multiple nanolayer stacks and multilayer bottom isolation region 140 with each nanolayer stack and multilayer bottom isolation region 140 located underneath a respective sacrificial gate structure 160 and associated gate spacer(s) 170.

The one or more S/D region canyons 175 may be formed by removing respective portions of the sacrificial nanolayers 106, active nanolayers 108, and multilayer bottom isolation region 140 that are between gate spacers 170 of adjacent or neighboring sacrificial gate structures 160. The one or more S/D region canyons 175 may be initially formed to a depth to stop at or below the top surface of the substrate structure 102, below the bottom surface of the multilayer bottom isolation region(s) 140, or the like.

The undesired portions of sacrificial nanolayers 106, active nanolayers 108, and bottom isolation region(s) 140 may be removed by etching or other subtractive removal techniques. The top surface of the substrate structure 102 may be used as an etch stop or other etch parameters may be controlled to stop the material removal at or below the substrate structure 102. As the gate spacers 170 and the sacrificial gate structures 160 may be utilized to protect the underlying portions of sacrificial nanolayers 106 and active nanolayers 108, respective sidewalls of the resulting nanolayer stacks may be substantially coplanar and substantially vertical with the outer sidewalls of the gate spacers 170 there above.

As used herein, “substantially vertical” sidewalls deviate from a direction normal to a major surface (e.g., top surface, etc.) of the substrate structure 102 by less than 5°, e.g., 0°, 1°, 2°, 3, 4°, or 5°, including ranges between any of the foregoing values.

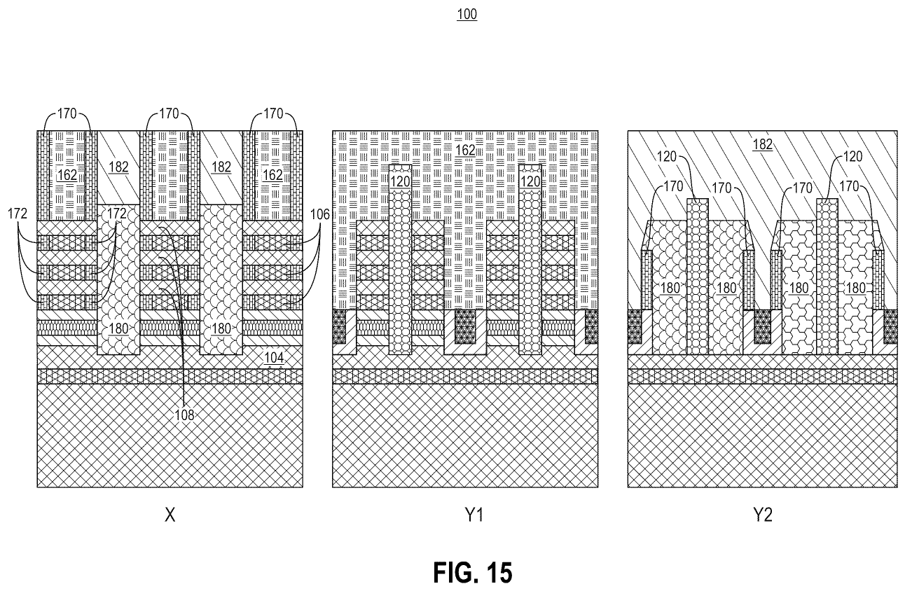

FIG. 15 depicts a fabrication structure cross-section view of the semiconductor IC device 100 that includes multilayer bottom isolation region 140, according to one or more embodiments of the disclosure. In the depicted fabrication stage, sacrificial nanolayers 106 may be laterally indented, inner spacers 172 may be formed in the lateral indents, respective source/drain (S/D) regions 180 may be formed, and interlayer dielectric (ILD) 182 may be formed.

The illustrated semiconductor IC device 100 may be further fabricated by forming horizontal or lateral indents within the sacrificial nanolayers 106 by laterally or horizontally removing respective portions of sacrificial nanolayers 106. The indents may be formed by a reactive ion etch (RIE) process, which can remove portions of the sacrificial nanolayers 106. The horizontal depth of the indents may be chosen to set a gate length for a replacement gate structure that is formed in place of one sacrificial gate structure 160. When the sacrificial nanolayers 106 are composed of SiGe and when active nanolayers 108 are Si, the directional RIE can use a boron-based chemistry or a chlorine-based chemistry, for example, which recesses or removes the exposed end portions of sacrificial nanolayers 106 (e.g., end portions of sacrificial nanolayers generally below gate spacer 170).

The illustrated semiconductor IC device 100 may be further fabricated by forming a respective inner spacer 172 within each indent. The one or more inner spacers 172 can be formed by ALD or CVD or any other suitable deposition technique that deposits a dielectric material within the indent(s), thereby forming the inner spacers 172. In some examples, the inner spacers 172 are composed of a low-x dielectric material (a material with a lower dielectric constant relative to SiO₂), SiN, SiO, SiBCN, SiOCN, SiCO, etc. or any other suitable dielectric material. In certain implementations, after the formation of the inner spacers 172, a directional etch process is performed to create substantially vertical sidewalls of the inner spacers 172 that are coplanar with the substantially vertical sidewalls of the active nanolayers 108 and/or of the gate spacers 170.

The illustrated semiconductor IC device 100 may be further fabricated by forming a respective S/D region 180 upon the substrate structure 102 within a S/D region canyon 175. For example, p-doped S/D regions 180 (shown by a first shape fill pattern) may be formed in a first formation sequence and n-doped S/D regions 180 (shown by a second shape fill pattern) may be formed in a second formation sequence, or vice versa. In a particular example, the S/D regions 180 with the shape fill pattern as depicted in the X cross-section may be p-doped S/D regions 180 and the S/D regions 180 with the second shape fill pattern may be n-doped S/D regions 180.

Each S/D region 180 may form either a source or a drain, respectively, of a respective transistor and is connected to respective end surfaces of the active nanolayers 108. Each S/D region 180 is composed of a semiconductor material and a dopant. As used herein, a “source/drain” region can be a source region or a drain region depending on doping type and subsequent wiring and application of voltages during operation of the applicable transistor.

The semiconductor material that provides each of the S/D regions 180 may be composed of one of the semiconductor materials mentioned above for the substrate structure 102. For example, the semiconductor material that provides the S/D region 180 can be compositionally the same, or compositionally different from each active nanolayer 108. The dopant that is present in the S/D regions 180 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “n-type” refers to the addition of impurities that contributes free electrons to an intrinsic semiconductor. In a silicon containing semiconductor material, examples of n-type dopants, include, but are not limited to, antimony, arsenic and phosphorous. When the semiconductor material is doped with a p-type dopant, the resulting S/D regions 180 may be referred to herein as being p-doped and when the semiconductor material is doped with a n-type dopant, the resulting S/D regions 180 may be referred to herein as being n-doped.

The S/D regions 180 may be epitaxially grown or formed. In some examples, the S/D regions 180 are formed by in-situ doped epitaxial growth. The use of an in-situ doping process is merely an example. For instance, one may instead employ an ex-situ process to introduce dopants into the S/D regions 180. Other doping techniques can be used to incorporate dopants in the S/D regions 180. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In examples, S/D epitaxial growth conditions promote in-situ Boron doped SiGe for p-type transistor and phosphorus or arsenic doped silicon or Si:C for n-type transistors.

In some examples, the epitaxial growth that forms the S/D region 180 occurs or is promoted from the top surface of the substrate structure 102, from the side surfaces of the active nanolayers 108, or the like, while epitaxial growth may be limited or does not occur from neighboring STI regions 150 or from the multilayer bottom isolation region 140.

In some implementations, epitaxial growth to form the one or more S/D regions 180 may overgrow above the upper surface of the sacrificial gate structure(s) 160 and be subsequently recessed such that the top surface of the S/D region(s) 180 may be substantially horizontal and above the top surface of the topmost active nanolayer 108 (e.g., to enable contact between the end surface of that active nanolayer 108 and the S/D region 180). In other implementations, the epitaxial grown crystalline surfaces (e.g., (111) angled or diamond crystalline surfaces) of the S/D region(s) 180 may be maintained.

For clarity, in the Y2 plane the S/D regions 180 may be directly connected, grown directly against, or the like, to at least the associated side surfaces of the isolation bars 120 and gate spacers 170. As such, the growth or formation of the S/D regions 180 may be confined by the isolation bars 120 and at least partially confined by the gate spacers 170. For clarity, S/D regions 180 may further directly contact the inner spacers 172 and may further directly contact the associated STI region 150.

The illustrated semiconductor IC device 100 may be further fabricated by forming ILD 182. ILD 182 may be formed by forming a blanket ILD over the S/D region(s) 180, over the gate spacers 170, and over the isolation bar 120, over the STI regions 150, and/or the like.

The ILD 182 can be any suitable material, such as, for example, porous silicates, carbon doped oxides, silicon dioxides, silicon nitrides, silicon oxynitrides, OPL, or other dielectric materials. Any known manner of forming the ILD 182 can be utilized. The ILD 182 can be formed using, for example, CVD, PECVD, ALD, flowable CVD, spin-on dielectrics, or PVD.

In an example, the ILD 182 may be formed to a thickness above the top surface of the sacrificial gate structures 160. Subsequently, a planarization process, such as a CMP, may be performed to remove excess ILD 182 material and to remove the sacrificial gate caps 164 of the sacrificial gate structures 160, thereby exposing the sacrificial gate 162 thereunder. The planarization may also partially remove some of the sacrificial gates 162 or may at least expose the sacrificial gate 162 of the sacrificial gate structures 160. The CMP may create a substantially planar or substantially horizontal top surface for the semiconductor IC device 100. In other words, the respective top surfaces of ILD 182, gate spacers 170, the sacrificial gates 162, may be substantially coplanar and/or substantially horizontal.

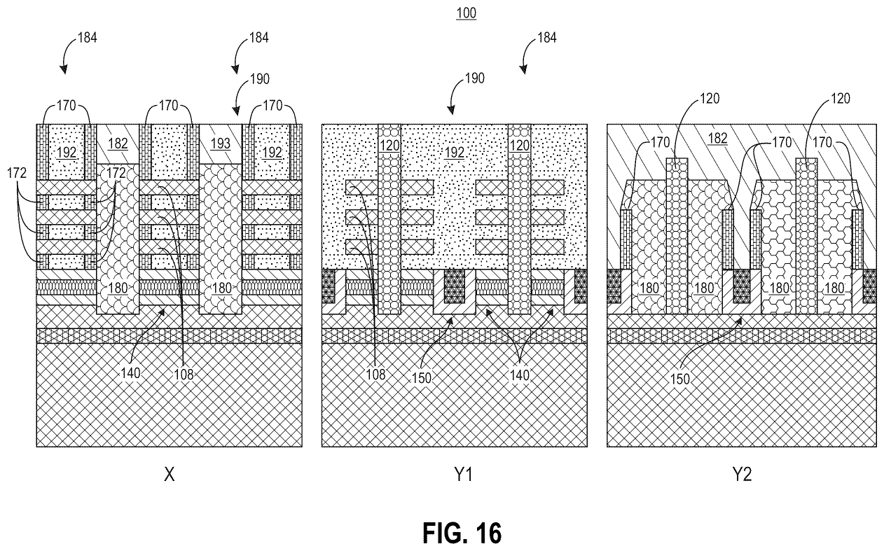

FIG. 16 depicts a fabrication structure cross-section view of the semiconductor IC device 100 that includes multilayer bottom isolation region 140, according to one or more embodiments of the disclosure. In the depicted fabrication stage, the sacrificial gate structures 160 may be removed, the active nanolayers 108 may be released, and replacement gate structures 190 may be formed.

The sacrificial gate structures 160 may be removed (and therefore not depicted) by removing the sacrificial gate 162 and sacrificial gate oxide by a removal technique, such as one or more series of etches which may form a gate replacement gate opening 184. For example, such removal may be accomplished by a wet chemical etching process in which one or more chemical etchants are used to remove the sacrificial gate 162 and sacrificial gate oxide of the sacrificial gate structures 160. Appropriate etchants may be used that remove the sacrificial gate 162 and/or sacrificial gate oxide selective to the gate spacers 170, active nanolayers 108, the sacrificial nanolayers 106, the STI regions 150, the inner spacers 172, the isolation bar 120, the substrate structure 102, multilayer bottom isolation region 140, or the like.

The active nanolayers 108 may be released by removing the sacrificial nanolayers 106 within respective replacement gate openings 184. The sacrificial nanolayers 106 may be removed by a removal technique, such as one or more series of etches. For example, the etching can include a wet chemical etching process in which one or more chemical etchants are used to remove the sacrificial nanolayers 106. Appropriate etchants may be used that remove the sacrificial nanolayers 106 selective to the active nanolayers 108, inner spacers 172, gate spacers 170, STI regions 150, isolation bar 120, substrate structure 102, multilayer bottom isolation region 140, or the like. After the removal of sacrificial nanolayers 106 void spaces may be formed above and/or below the active nanolayers 108.

Further, in the depicted fabrication stage, a replacement gate structure 190 is formed within the respective replacement gate openings 184 upon the isolation bar 120, upon the isolation bar 120, around the active nanolayers 108, upon STI regions 150, and upon multilayer bottom isolation region 140.

The replacement gate structure(s) 190 may be formed by initially forming an interfacial layer (not shown) on the gate spacers 170, on the active nanolayers 108, on the inner spacers 172, on the substrate structure 102, on the STI regions 150, upon the isolation bar 120, and upon multilayer bottom isolation region 140, etc. that are interior to and/or upon the respective surfaces interior to the replacement gate openings 184. The interfacial layer can be deposited by any suitable techniques, such as ALD, CVD, PVD, thermal oxidation, combinations thereof, or other suitable techniques.

The replacement gate structure(s) 190 may be further formed by forming a high-x layer (not shown) upon the exposed surfaces of the interfacial layer. The high-x layer can be deposited by any suitable techniques, such as ALD, CVD, metal-organic CVD (MOCVD), PVD, thermal oxidation, combinations thereof, or other suitable techniques. A high-x material is a material with a higher dielectric constant than that of SiO₂, and can include e.g., LaO, AlO, ZrO, TiO, Ta₂O₅, Y₂O₃, SrTiO₃(STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), or other suitable materials. The high-x layer can include a single layer or multiple layers, such as metal layer, liner layer, wetting layer, and adhesion layer. In other embodiments, the high-x layer can include, e.g., Ti, Ag, Al, TiAlN, TaC, TaCN, TaSiN, Mn, Zr, TiN, TaN, Ru, Mo, Al, WN, Cu, W, or any suitable materials.

The replacement gate structure(s) 190 may be further formed by depositing a work function (WF) gate (not shown) upon the high-x layer. The WF gate can be comprised of a conductor or metal, such as, e.g., copper (Cu), cobalt (Co), aluminum (Al), platinum (Pt), gold (Au), tungsten (W), titanium (Ti), nitride (N³⁻) or any combination thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In general, the WF gate sets the threshold voltage (Vt) of the transistor(s). The high-x layer may separate the WF gate from the active nanolayers 108. Other metals that may be desired to further fine tune the effective work function (eWF) and/or to achieve a desired resistance value associated with current flow through the replacement gate structure 190 in the direction parallel to the plane of the active nanolayers 108.

The replacement gate structure(s) 190 may be further formed by depositing a conductive gate 192. In an example, when none of the previous replacement gate material(s) are utilized in the replacement gate structures 190, the conductive gate 192 may be formed upon the same or similar surfaces as those upon which the interfacial layer, described above, may be formed. In other examples, when one or more of the interfacial layer, the high-x layer, the WF gate, or the like, are utilized in the replacement gate structures 190, the conductive gate 192 may be formed upon the most recent structural formation thereof.

The conductive gate 192 can be comprised of a conductor material and/or metal, such as but not limited to, e.g., tungsten, aluminum, ruthenium, rhodium, cobalt, copper, tantalum, titanium, carbon nanowire materials including graphene, or the like. The conductor material and/or metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering.

After the replacement gate structure 190 formation, the top surface of the semiconductor IC device 100 may be planarized by a planarization technique such as a CMP, mechanical grinding process, or the like. After the planarization technique, respective top surfaces of the gate spacers 170, replacement gate structures 190, isolation bar 120, and ILD 182, or the like, may be substantially horizontal and/or may be substantially coplanar.

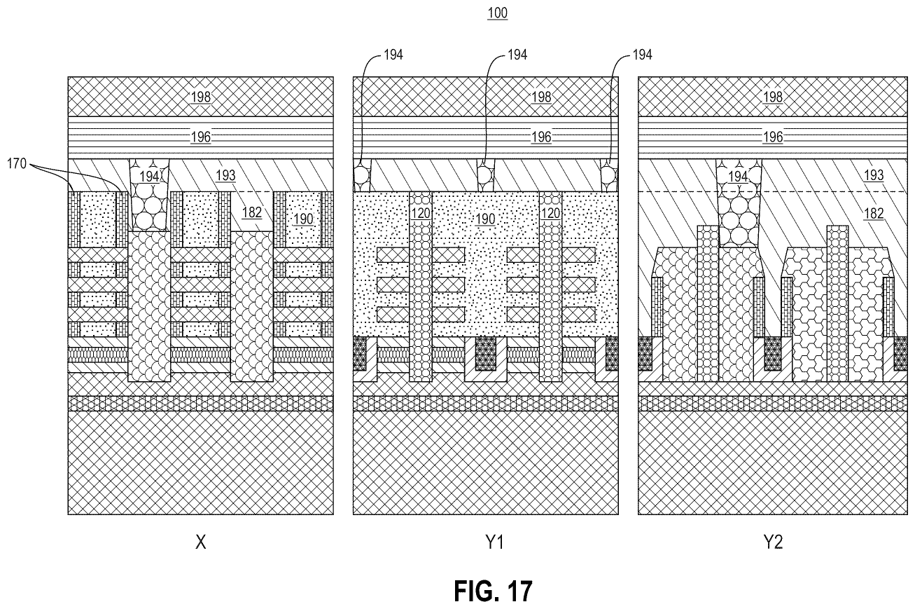

FIG. 17 depicts a fabrication structure cross-section view of the semiconductor IC device 100 that includes multilayer bottom isolation region 140, according to one or more embodiments of the disclosure. In the depicted fabrication stage, a frontside contact ILD 193 may be formed, frontside contacts 194 may be formed, frontside back end of line (BEOL) network 196 may be formed, and a carrier wafer 198 may be attached.

The frontside contact ILD 193 may be formed upon respective top surfaces of replacement gate structure(s) 190, ILD 182, and gate spacers 170. The frontside contact ILD 193 may be formed by depositing a dielectric material, such as, for example, porous silicates, carbon doped oxides, silicon dioxides, silicon nitrides, silicon oxynitrides, or other dielectric materials.

The illustrated semiconductor IC device 100 may be further fabricated by forming frontside contacts 194 within the frontside contact ILD 193 and/or the ILD 182. The frontside contacts 194 may be formed by patterning respective frontside contact openings within frontside contact ILD 193 and/or ILD 182, respectively, from the frontside (i.e., from above the semiconductor IC device 100, as depicted, downward to respective structures thereof). The frontside contact 194 may be in direct or indirect physical and electrical contact with respective regions, such as S/D region 180, replacement gate structure 190, or the like.

The frontside contacts 194 may be formed by initially forming frontside contact opening(s). The frontside contact(s) 194 may be further formed by depositing conductive material such as metal into the respective frontside contact opening(s). In an example, frontside contact(s) 194 may be formed by depositing a liner, such as Ni, NiPt or Ti, etc. into the contact opening(s), depositing an adhesion liner, such as TiN, TaN, etc. upon the liner, and by depositing a conductive fill, such as Al, Ru, W, Co, Cu, etc. upon the metal adhesion liner. Subsequently, a planarization process, such as a CMP process or a mechanical grinding process, may remove excess portions of the liner, the metal adhesion liner, and the conductive fill. Subsequently, the respective top surfaces of frontside contact(s) 194 and the frontside contact ILD 193 may be substantially horizontal and/or substantially coplanar. In embodiments, the frontside contact(s) 194 are fabricated in middle-of-line (MOL) fabrication operations and may be illustrations of MOL frontside contacts.

In the semiconductor IC device fabrication industry, there are three sections referred to in a build: front-end-of-line (FEOL), back-end-of-line (BEOL), and the section that connects those two together, the middle-of-line (MOL). The FEOL is made up of the semiconductor devices, e.g., FEOL transistors, the BEOL is made up of interconnects and wiring, and the MOL is an interconnect between the FEOL and BEOL that includes material to prevent the diffusion of BEOL metals to FEOL devices.

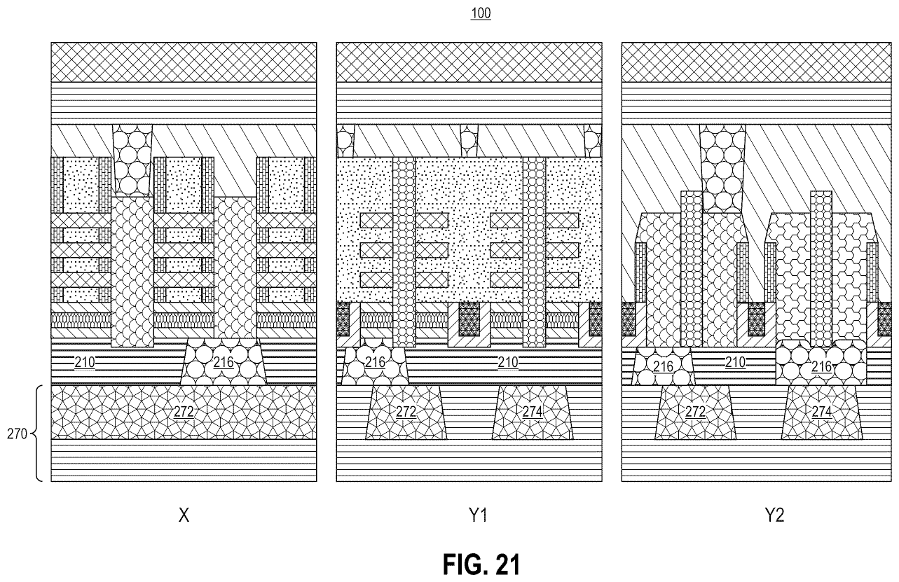

BEOL is the second portion of IC fabrication where the individual devices (e.g., transistors, capacitors, resistors, etc.) become interconnected with wiring on the semiconductor IC device, e.g., the metallization layer or layers of a wafer. BEOL includes contacts, insulating layers (dielectrics), metal levels, and bonding sites for chip-to-package connections. In the BEOL, part of the fabrication stage contacts (pads), wires, vias and dielectric structures are formed. For modern IC processes, more than one metal layers may be added in the BEOL. In the present example, there are multiple BEOL levels each on opposites sides of the semiconductor IC device 100. First, a frontside BEOL network 196 may formed on the frontside of the semiconductor device 100. Subsequently, a backside BEOL network 270, as depicted in FIG. 21, may be formed.

In the depicted example, the frontside BEOL network 196 is formed over the frontside contact ILD 193 and upon the frontside contacts 194. Respective wires within the frontside BEOL network 196 may be electrically connected to the one or more S/D regions 180, to the one or more replacement gate structure(s) 190, or the like, by respective frontside contact(s) 194. For example, respective wire(s) within the frontside BEOL network 196 may be electrically connected to appropriate one or more S/D regions 180 by a frontside contact 194 and another and different group of respective wire(s) within the frontside BEOL network 196 may be electrically connected to appropriate one or more replacement gate structures 190 by a different frontside contact 194.

The frontside BEOL network 196 is located directly on the frontside surface of the MOL structure (e.g., contact ILD 193, frontside contact(s) 194, etc.). The frontside BEOL network 196 can include one or more dielectric material layers (including one of the dielectric materials mentioned above for the frontside ILD 182) and contains metal wires (the metal wires can be composed of any electrically conductive metal or electrically conductive metal alloy) embedded therein. In some embodiments, the frontside metal wires within the frontside BEOL network 196 are composed of Cu. The frontside BEOL network 196 can include “x” numbers of frontside metal levels, wherein “x” is an integer starting from 1. The frontside BEOL network 196 may further contain conductive pads that are connected to one or more of the metal wires and may be used to connect the semiconductor IC device 100 to an external and/or higher-level structure, such as a chip carrier, motherboard, or the like.

The illustrated semiconductor IC device 100 may be further fabricated by next bonding carrier wafer 198 to the frontside BEOL network 196. The carrier wafer 198 can include one of the semiconductor materials mentioned above for the semiconductor structure and the carrier wafer 198 may be attached to the semiconductor IC device 100 by a wafer-to-wafer bonding technique.

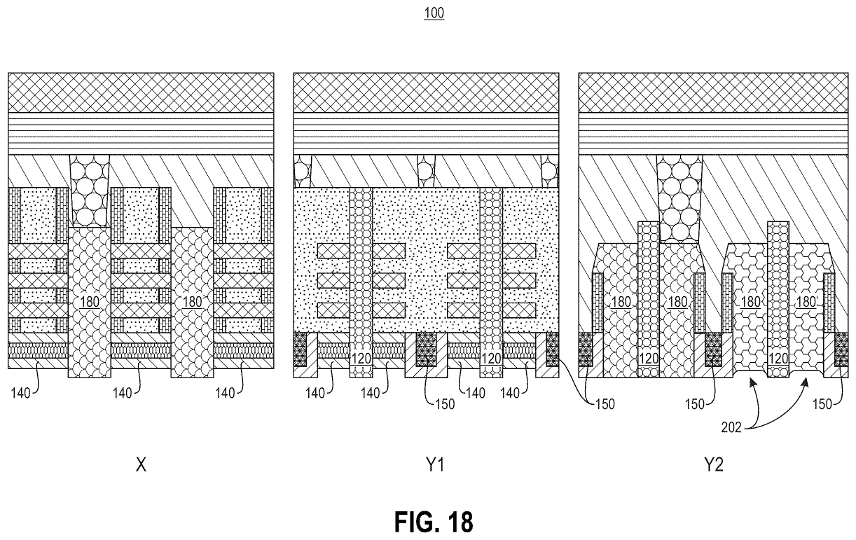

FIG. 18 depicts a fabrication structure cross-section view of the semiconductor IC device 100 that includes multilayer bottom isolation region 140, according to one or more embodiments of the disclosure. In the depicted fabrication stage, substrate structure 102 is removed.

The substrate structure 102 may be removed by flipping the semiconductor IC device 100 (not shown) and removing the lower substrate 101 using any removal technique, such as a combination of wafer grinding, CMP, dry, and/or wet etch. In the example depicted, lower substrate 101 is removed by an etch that utilizes etch stop layer 103 as the etch stop. In this example, removal of lower substrate 101 exposes the bottom surface of etch stop layer 103. The etch stop layer 103 may be removed by a subtractive removal technique such as a CMP, dry and/or wet etch. Upon removal of the etch stop layer 103, the bottom surface upper substrate 104 is exposed. The removal of etch stop layer 103 may be selective to the material of upper substrate 104. For example, etch stop layer 103 is removed by an etch that utilizes upper substrate 104 as the etch stop.

The upper substrate 104 may be removed by one or more etch process(es). The etch may be timed or otherwise controlled to remove the material of substrate structure 102 selective to the STI regions 150, to the isolation bars 120, to the multilayer bottom isolation regions 140, to the S/D regions 180, or the like.

For clarity, in some implementations, as depicted, one type of S/D regions 180 may be gouged, and therefore may include a gouge 202, by the etch that removes the upper substrate 104 from the semiconductor IC device 100. For example, those S/D regions 180 that are comprised of SiGe may not be substantially affected and may not include a gouge 202 by the etch that removes the upper substrate 104, when the upper substrate is composed of Si. Similarly, those S/D regions 180 that are comprised of Si may be gouged, and therefore include gouge 202, by the etch that removes the upper substrate 104, when the upper substrate is also composed of Si.

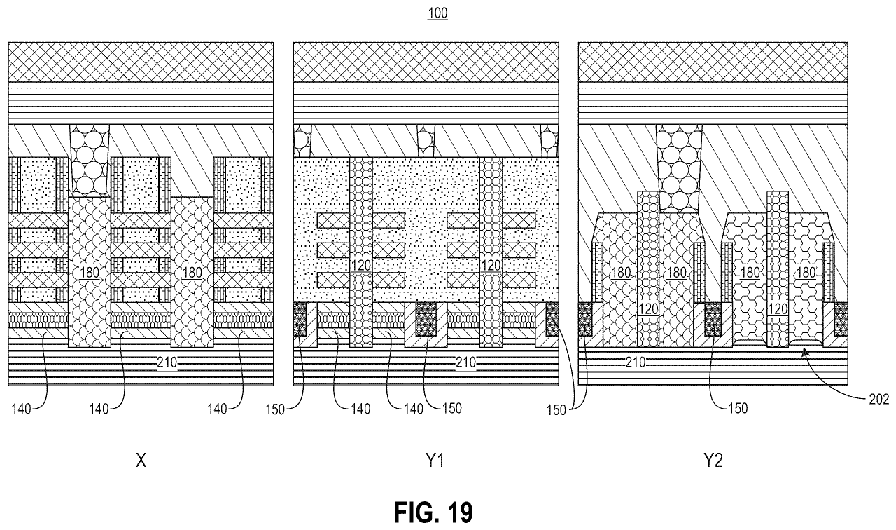

FIG. 19 depicts a fabrication structure cross-section view of the semiconductor IC device 100 that includes multilayer bottom isolation region 140, according to one or more embodiments of the disclosure. In the depicted fabrication stage, backside ILD 210 may be formed upon the exposed backside of the semiconductor IC device 100.

The backside ILD 210 may be formed upon the respective exposed surfaces of the STI regions 150, the multilayer bottom isolation regions 140, the to the isolation bars 120, the S/D regions 190, and the like. The backside ILD 210 may be formed by depositing a dielectric material, such as, for example, porous silicates, carbon doped oxides, silicon dioxides, silicon nitrides, silicon oxynitrides, or other dielectric materials. In an example, the backside ILD 210 and the ILD 182 may be composed of the same material(s). Any appropriate deposition technique for forming the backside ILD 210 can be utilized. For clarity, backside ILD 210 may further be formed within the one or more gouges 202 that may exist within applicable S/D regions 180.

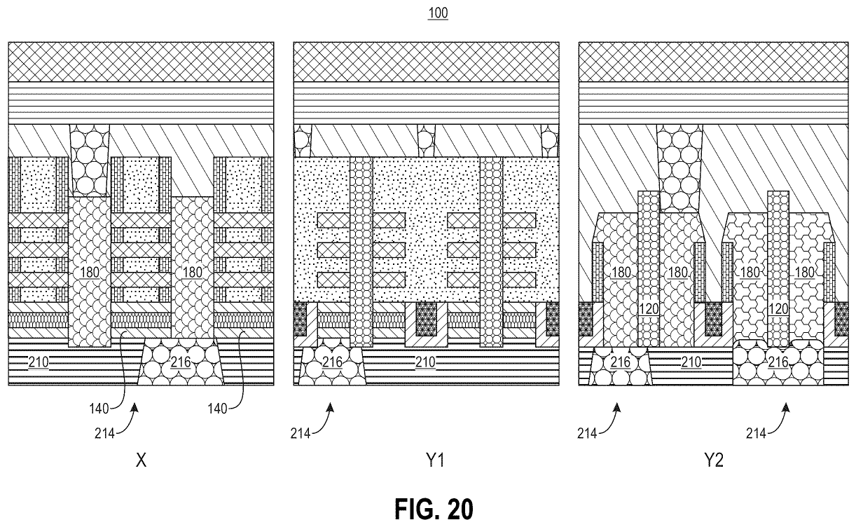

FIG. 20 depicts a fabrication structure cross-section view of the semiconductor IC device 100 that includes multilayer bottom isolation region 140, according to one or more embodiments of the disclosure. In the depicted fabrication stage, backside contact opening(s) 214 may be formed and a respective backside contact 216 may be formed within a particular backside contact opening 214.

The backside contact opening(s) 214 may be formed by the same or shared lithography and etch process(es), or sequential lithography and etch processes. In such process(es), a mask (not shown) may be applied to the backside of the semiconductor IC device 100 and patterned. Openings in the patterned mask may sequentially expose the portion(s) of the underlying backside ILD 210. Using the patterned mask an etchant may remove the exposed portions of the ILD 210 and may expose the inline S/D region 180 and may further partially expose the STI region 150 and the isolation bar 120. The etch may be selective to the respective material(s) of the STI regions 150, to the isolation bar 120, and to multilayer bottom isolation region 140. A respective backside contact opening 214 may be formed to expose the associated one or more inline S/D regions 180 there above (e.g., the S/D regions 180 that may not be connected to the frontside BEOL network 196). For clarity, due to the multilayer bottom isolation region 140, a traditional backside contact placeholder is not necessary and the removal of such placeholder is therefore not needed at this or similar fabrication stages.

The illustrated semiconductor IC device 100 may be further fabricated by forming a backside contact 216 within a respective backside contact opening 214. The backside contacts 216 may be formed by depositing conductive material, such as metal, into the respective backside contact opening(s) 214. In an example, backside contact(s) 216 may be simultaneously formed by depositing a liner, such as Ni, NiPt or Ti, etc. onto the backside of semiconductor IC device 100 and into the backside contact openings 214, depositing an adhesion liner, such as TiN, TaN, etc. upon the liner, and by depositing a conductive fill, such as Al, Ru, W, Co, Cu, etc. upon the adhesion liner. In the depicted illustration, the backside contact 216 may be formed within the backside contact opening 214 directly against the associated exposed one or more S/D region(s) 180.

Subsequently, a planarization process, such as a CMP, may expose a bottom surface of the backside ILD 210. As a result, the respective backside or bottom surfaces of backside contact(s) 216 and backside ILD 210 may be substantially horizontal and/or substantially coplanar.

FIG. 21 depicts a fabrication structure cross-section view of the semiconductor IC device 100 that includes multilayer bottom isolation region 140, according to one or more embodiments of the disclosure. In the depicted fabrication stage, backside BEOL network 270 may be formed.

The backside BEOL network 270, such as a backside power distribution network (BSPDN) may be formed upon the backside contact(s) 216 and upon the backside ILD 210. The backside BEOL network 270 may include signal wires for signal routing and power wires for providing power potential, such as a VDD power wire 272 and/or a VSS power wire 274. The backside BEOL network 270 may allow for the distribution of power wires and signal wires between both the frontside and backside of the semiconductor IC device. The backside BEOL network 270 may further allow for the full or partial decoupling of signal routing and/or power routing and/or allows for dividing or splitting power wires and/or signal wires between both the frontside and backside of the semiconductor IC device. By incorporating the backside BEOL network 270, routing congestion may be reduced, which may lead to further semiconductor IC device 100 scaling. For example, semiconductor IC devices that incorporate a backside BEOL network can result in a 30% area reduction and improved current-resistance (IR) drop compared to typical semiconductor IC devices that include solely a frontside BEOL network.

The backside BEOL network 270 may be indirectly electrically and/or indirectly physically connected to the one or more S/D regions 180 by way of a backside contact 216. The backside BEOL network 270 can include one or more dielectric material layers and contains backside conductive wires and/or interconnects, such as VIAs, embedded therein. In some embodiments, the backside wires within the backside BEOL network 270 are composed of Cu. The backside BEOL network 270 can include “x” numbers of backside metal levels, wherein “x” is an integer starting from 1. If not included in frontside BEOL network 196, backside BEOL network 270 may further contain conductive pads that are connected to one or more of the backside metal wires and may be used to connect the semiconductor IC device 100 to the external and/or higher-level structure.

In an example, signal routing and power routing is effectively split between the frontside BEOL network 196 and the backside BEOL network 270. For example, at least 90% of the frontside metal wires (e.g., furthest from the transistors 100.2, 100.4, 100.6, 100.8, and 100.10) are signal routing metal wires and the remainder frontside metal wires which are usually present in metal levels closest to the transistors, can be used as power routing wires. Further in this example, at least 90% of the backside metal wires that are in metal levels closest to the backside contacts are power routing metal wires and the remainder backside metal wires which are usually present in metal levels furthest away from the backside contacts, can be used as signal routing wires. Power routing wires may be less dense than signal routing wires. A signal routing wire is defined herein as a conductive feature, such as a wire, interconnect, or the like, that is configured to electrically carry a functional or logical potential or signal that is to change or is otherwise dynamic over time. A power routing wire is defined herein as a conductive feature, such as a wire, trace, plane, or the like, that is configured to electrically carry power potential. For example, a power routing wire carries or otherwise has a functional power potential, such as VDD, VSS, or the like.

Semiconductor IC device 100 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

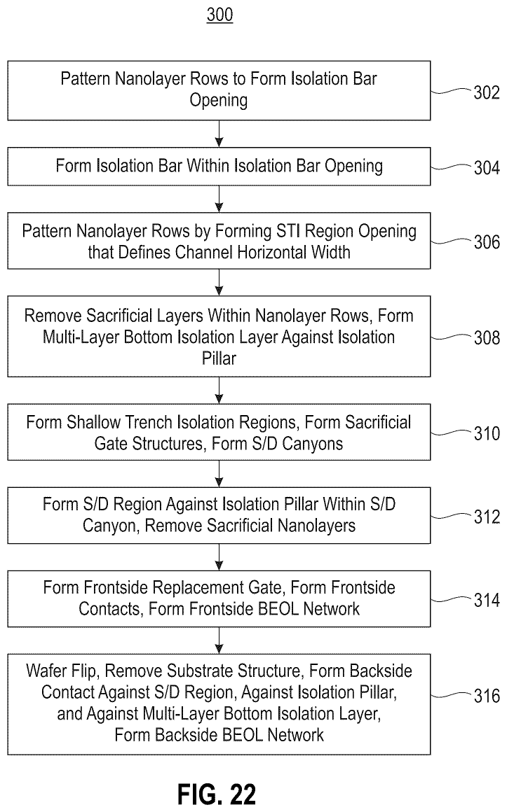

FIG. 22 depicts a flow diagram illustrating a method 300 to fabricate a semiconductor IC device, such as semiconductor IC device 100, though the fabrication operations described in method 300 may be used to fabricate other types of semiconductor IC devices. The depicted fabrication operations of method 300 may be illustratively depicted and described with reference to one or more of FIG. 3 through FIG. 21 of the drawings. The method 300 depicted herein is illustrative. There can be many variations to the diagram or operations described therein without departing from the spirit of the embodiments. For instance, the operations can be performed in a differing order, or operations can be added, deleted, or modified.

At block 302, method 300 may begin with forming nanolayers, such as sacrificial nanolayers 106 and active nanolayers 108, upon a substrate structure 102 and patterning the nanolayers into nanolayer rows 109 by forming isolation region opening(s) 116. At block 304, method 300 may continue with forming isolation bar 120 within a respective isolation region opening 116. At block 306, method 300 may continue with pattering the nanolayer row(s) 109 by forming STI region opening(s) 121.

At block 308, method 300 may continue with removing the bottom most sacrificial nanolayer 106 and the sacrificial nanolayer(s) 107 within the nanolayer row(s) 109 and subsequently forming the multilayer bottom isolation region 140 in place thereof against the isolation bar 120.

At block 310, method 300 may continue with forming an STI region 150, with forming sacrificial gate structures 160, and with forming S/D canyons 175. At block 312, method 300 may continue with forming a S/D region 180 against the isolation bar 120 within the S/D canyon, and with removing the sacrificial nanolayers 106 underneath the sacrificial gate structures 160.

At block 314, method 300 may continue with forming replacement gate 190, with forming frontside contacts 194, and with forming the frontside BEOL network 196. At block 316, method 300 may continue with flipping the semiconductor IC device, with removing the substrate structure 102, and with forming a backside contact 216 against the isolation bar 120, against the S/D region 180, against the STI region 150, and against the multilayer bottom isolation region 140. Block 314 may further include forming backside BEOL network 270.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
an isolation bar;
nanolayer channels in direct contact with the isolation bar;
a source/drain region in direct contact with the isolation bar and in direct contact with the nanolayer channels; and
a multilayer bottom isolation region in direct contact with the isolation bar.

2. The semiconductor IC device of claim 1, wherein the source/drain region is also in direct contact with the multilayer bottom isolation region.

3. The semiconductor IC device of claim 2, further comprising:
a backside contact in direct contact with a bottom surface of the source/drain region and in direct contact with a bottom surface of the multilayer bottom isolation region.

4. The semiconductor IC device of claim 3, wherein a bottom surface of the isolation bar is below a bottom surface of the multilayer bottom isolation region.

5. The semiconductor IC device of claim 4, further comprising:
a gate structure in direct contact with the nanolayer channels, in direct contact with the isolation bar, and in direct contact with a top surface of the multilayer bottom isolation region.

6. The semiconductor IC device of claim 5, wherein a top surface of the multilayer bottom isolation region is substantially coplanar with a bottom surface of the gate structure.

7. The semiconductor IC device of claim 6, further comprising:
a shallow trench isolation (STI) region in direct contact with the multilayer bottom isolation region.

8. The semiconductor IC device of claim 7, wherein the backside contact is also in direct contact with the STI region and wherein a top surface of the STI region is substantially coplanar with the top surface of the multilayer bottom isolation region.

9. The semiconductor IC device of claim 1, wherein the multilayer bottom isolation region comprises:
a bottom dielectric layer composed of a first dielectric material;
a middle dielectric layer; and
a top dielectric layer composed of the first dielectric material.

10. The semiconductor IC device of claim 9, wherein the middle dielectric layer is composed of a second dielectric material different than the first dielectric material.

11. The semiconductor IC device of claim 9, wherein respective sidewalls of the bottom dielectric layer, the middle dielectric layer, and the top dielectric layer are in direct contact with the isolation bar.

12. A semiconductor integrated circuit (IC) device comprising:
an isolation bar;
nanolayer channels in direct contact with the isolation bar; and
a multilayer bottom isolation region in direct contact with the isolation bar; and
wherein respective sidewalls of the nanolayer channels are substantially coplanar with a sidewall of the multilayer bottom isolation region.

13. The semiconductor IC device of claim 12, further comprising:
a source/drain region in direct contact with the isolation bar and in direct contact with the nanolayer channels.

14. The semiconductor IC device of claim 13, wherein the source/drain region is also in direct contact with the multilayer bottom isolation region.

15. The semiconductor IC device of claim 14, further comprising:
a backside contact in direct contact with a bottom surface of the source/drain region and in direct contact with a bottom surface of the multilayer bottom isolation region.

16. The semiconductor IC device of claim 15, wherein a bottom surface of the isolation bar is below a bottom surface of the multilayer bottom isolation region.

17. The semiconductor IC device of claim 16, further comprising:
a gate structure in direct contact with the nanolayer channels, in direct contact with the isolation bar, and in direct contact with a top surface of the multilayer bottom isolation region.

18. The semiconductor IC device of claim 17, wherein a top surface of the multilayer bottom isolation region is substantially coplanar with a bottom surface of the gate structure.

19. The semiconductor IC device of claim 18, further comprising:
a shallow trench isolation (STI) region in direct contact with the multilayer bottom isolation region.

20. A semiconductor integrated circuit (IC) device comprising:
an isolation bar;
nanolayer channels in direct contact with the isolation bar; and
a multilayer bottom isolation region in direct contact with the isolation bar; and
wherein the nanolayer channels and the multilayer bottom isolation region share a same substantially vertical bisector.
